(19) United States
(12) Patent Application Publication
(10) Pub. No.: US 2013/0257677 A1
(43) Pub. Date: Oct. 3, 2013

(54) HYBRID VARIABLE CAPACITOR, RF APPARATUS, METHOD FOR MANUFACTURING HYBRID VARIABLE CAPACITOR AND METHOD FOR TUNING VARIABLE CAPACITOR

(71) Applicant: SAMSUNG ELECTRO-MECHANICS CO., LTD., Suwon-si (KR)

(72) Inventor: Chan Yong JEONG, Gyeonggi-do (KR)

(73) Assignee: SAMSUNG ELECTRO-MECHANICS CO., LTD., Suwon-si (KR)

(21) Appl. No.: 13/801,877

(22) Filed: Mar. 13, 2013

(30) Foreign Application Priority Data
Mar. 27, 2012 (KR) 10-2012-0031120

(51) Int. Cl. H03H 5/12; H01Q 1/50

(52) U.S. Cl. CPC H03H 5/12; H01Q 1/50
USPC 343/861; 327/586

(57) ABSTRACT

Disclosed herein are a hybrid variable capacitor, an RF apparatus, a method for manufacturing a hybrid variable capacitor, and a method for tuning a variable capacitor. The hybrid variable capacitor used in a tunable matching network includes: a metal-insulator-metal (MIM) cap array including one or more MIM capacitors and having varied capacitance equivalent to values of a lower-bit region among digital values corresponding to capacitance to be tuned; and a MOS varactor connected in parallel to the MIM cap array and having varied capacitance equivalent to values of an upper-bit region among the digital values.

### CROSS REFERENCE(S) TO RELATED APPLICATIONS

This application claims the benefit under 35 U.S.C. Section 119 of Korean Patent Application Serial No. 10-2012-0031120, entitled “Hybrid Variable Capacitor, RF Apparatus, Method for Manufacturing Hybrid Variable Capacitor and Method for Tuning Variable Capacitor” filed on Mar. 27, 2012, which is hereby incorporated by reference in its entirety into this application.

### BACKGROUND OF THE INVENTION

1. Technical Field

The present invention relates to a hybrid variable capacitor, an RF apparatus, a method for manufacturing a hybrid variable capacitor, and a method for tuning a variable capacitor, and more particularly, to a hybrid variable capacitor, an RF apparatus, a method for manufacturing a hybrid variable capacitor, and a method for tuning a variable capacitor capable of extending a tuning range while reducing a chip size.

2. Description of the Related Art

In line with the development of wireless communication technologies, 4G mobile communication represented by LTE (Long Term Evolution) has emerged in addition to current 3G mobile communication. The addition of 4G mobile communication network functions to the current 3G mobile communication network increases schemes that can be supported by a single mobile phone. Thus, beyond a current level of RF performance, mobile phones are further required to cover various frequency bands by a single RF chain and optimize front-end matching including an antenna while in service to optimize power consumed in a power amplifier (PA).

In order to implement such functions, a tunable matching circuit block is required to be added to an existing RF front-end having a fixed structure to support flexibility. A scheme of applying a tunable matching network includes an open loop scheme and a closed loop scheme. For example, the open loop scheme is a scheme of tuning a variable capacitor value with reference to a predefined look-up table, and the closed loop scheme is a scheme of performing arithmetic operation based on a mismatched signal detected by an impedance detector and tuning a variable capacitor value.

Here, for tunability performance, a variable capacitor is used as a variable element. The variable capacitor as a variable element determines a value Q in a matching circuit block, the most important factor in the matching circuit.

The related art selectively employs any one of a varactor structure and a capacitor array scheme to implement a variable capacitor.

First, the varactor scheme will be described. A varactor has a capacitance value which is continuously changed as an analog voltage is applied thereto. For example, in case of a BST varactor, a DAC (Digital to Analog Converter) is required to apply an analog voltage. When a certain value is input through a digital control signal in a control IC in which the BST varactor is used, the value is converted into a corresponding analog voltage by the DAC and applied to the varactor. The BST type varactor has advantageously excellent power handling performance but disadvantageously has a narrow capacitance tuning range overall.

The capacitor array scheme may be implemented through, for example, an MEMS process. In order to operate the capacitor implemented through the MEMS process, generally, a high voltage of about 30V to 50V is required, so a charge pump and a high voltage driver are required. The capacitor array using the MEMS process is able to form a broad tuning range but has disadvantages in that a high voltage process should be performed and costs are increased accordingly.

Also, the capacitor array scheme may be implemented as a metal-insulator-metal (MIM) capacitor by using a general CMOS process. The MIM capacitor can be fabricated through a standard CMOS process and controlled by applying a digital signal to a switch without the necessity of a DAC. The use of a CMOS advantageously extends a tuning range while most advantageously reduces a size and allows competitive pricing, but disadvantageously has a limitation in increasing resolution because of the size of a unit capacitor and the tuning range in implementing the capacitor array scheme. For example, in case of using identical 5-bit controlling, a step size is determined according to a tuning range. When the tuning range is set to be 0.5˜3.6 pF, a step size, i.e., a unit capacitor, is 0.091 pF, and when the tuning range is set to 1.0˜6.89 pF, a step size, i.e., a unit capacitor, is 0.1 pF, and when the tuning range is set to be 1.0˜7.2 pF, the unit capacitor as a step size is 0.2 pF. Thus, when 8-bit controlling is used, MSB is 2⁷=128, subsequently 128C, a size equivalent to 128 times the unit capacitor, should be used. As a result, a chip area is rapidly increased, so it is difficult to implement 5 bits or more according to the related art.

### RELATED ART DOCUMENT

### Patent Documents

(Patent Document 1) U.S. Patent Laid-Open Publication No. US 2009-0128428

(Patent Document 2) U.S. Pat. No. 7,764,125

### SUMMARY OF THE INVENTION

An object of the present invention is to provide a hybrid variable capacitor technique required for implementing an effective tunable matching network (TMN) by complementing shortcomings of an existing scheme.

According to an exemplary embodiment of the present invention, there is provided a hybrid variable capacitor used in a tunable matching network, including: a metal-insulator-metal (MIM) cap array including one or more MIM capacitors and having varied capacitance equivalent to values of a lower-bit region among digital values corresponding to capacitance to be tuned; and a MOS varactor connected in parallel to the MIM cap array and having varied capacitance equivalent to values of an upper-bit region among the digital values.

The hybrid variable capacitor may further include: one or more FET switches connected to the respective capacitors of the MIM cap array and performing a switching operation according to the values of the lower-bit region to allow the MIM cap array to have varied capacitance.

The MOS varactor may have varied capacitance according to an analog voltage generated from a digital-to-analog converter (DAC) which has received the values of the upper-bit region.

The MOS varactor may perform coarse tuning, and the MIM cap array may perform fine tuning.

According to another exemplary embodiment of the present invention, there is provided an RF apparatus including: an antenna; an RF module transmitting an RF signal to the antenna or receiving an RF signal from the antenna; a tunable matching network installed between the antenna and the RF module and performing matching on a front end of the RF module by tuning capacitance of a variable capacitor under the control of a signal processing module, the variable capacitor being a hybrid variable capacitor including a metal-insulator-metal (MIM) cap array having varied capacitance equivalent to values of a lower-bit region among digital values corresponding to capacitance to be tuned, and a MOS varactor connected in parallel to the MIM cap array and having varied capacitance equivalent to values of an upper-bit region among the digital values; and the signal processing module connected to a back end of the RF module, processing an RF signal received from the RF module or a signal to be transmitted to the RF module, and controlling capacitance of the hybrid variable capacitor such that matching is performed in the matching network.

The hybrid variable capacitor may further include: one or more FET switches connected to the respective capacitors of the MIM cap array and performing a switching operation according to the values of the lower-bit region to allow the MIM cap array to have varied capacitance.

The matching network may further include: a digital-to-analog converter (DAC) generating an analog voltage for controlling the MOS varactor of the hybrid variable capacitor upon receiving the values of the upper-bit region.

The matching network may further include: a decoder receiving digital values corresponding to the capacitance to be tuned from the signal processing module and splitting the digital values into the values of the upper-bit region and the values of the lower-bit region.

The MOS varactor may perform coarse tuning, and the MIM cap array may perform fine tuning.

The signal processing module may include: a baseband signal processing unit processing the RF signal received from the RF module or the signal to be transmitted to the RF module; and a controller controlling the capacitance of the hybrid variable capacitor such that matching is performed in the matching network.

The RF apparatus may further include: an impedance detection unit detecting impedance of the matching network and transmitting the detected signal to the controller to allow the controller to tune the capacitance such that the matching network is matched, when the matching network is mismatched.

According to another exemplary embodiment of the present invention, there is provided a method for manufacturing a hybrid variable capacitor used in a tunable matching network, including: forming a metal-insulator-metal (MIM) cap array including one or more MIM capacitors on a substrate through a CMOS process so that the capacitance of the MIM cap array is able to be coarsely tuned according to values of a lower-bit region among digital values corresponding to the capacitance of the hybrid variable capacitor to be tuned; and forming a MOS varactor on the substrate through the CMOS process to be connected in parallel to the MIM cap array so that the capacitance of the MOS varactor is able to be finely tuned according to values of an upper-bit region among the digital values.

The forming of the MIM cap array may include: forming one or more FET switches which is connected to the respective MIM capacitors and performs a switching operation according to the values of the lower-bit region to allow the MIM cap array to have varied capacitance.

According to another exemplary embodiment of the present invention, there is provided a variable capacitor tuning method for tuning capacitance of a hybrid variable capacitor used in a tunable matching network, including: receiving digital values corresponding to capacitance to be tuned and splitting the digital values into values of a lower-bit region and values of an upper-bit region; performing coarse tuning on a MOS varactor of a hybrid variable capacitor comprising a metal-insulator-metal (MIM) cap array and the MOS varactor to have varied capacitance equivalent to the split values of the upper-bit region; performing fine tuning on the MIM cap array to have varied capacitance equivalent to the split values of the lower-bit region; and completing tuning final capacitance by synthesizing the capacitance of the coarsely tuned MOS varactor and the capacitance of the finely tuned MIM cap array.

In the performing of fine tuning, FET switches connected to respective capacitors of the MIM cap array may be switched according to the values of the lower-bit region to allow the MIM cap array to have varied capacitance.

The performing of coarse tuning may include: generating an analog voltage for controlling the MOS varactor upon receiving the values of the upper-bit region.

In the splitting of the digital values into the values of the lower-bit region and the values of the upper-bit region, the digital values corresponding to the capacitance to be tuned may be received and split into the values of the lower-bit region and the values of the upper-bit region according to a control logic.

The method may further include: calculating the digital values corresponding to the capacitance to be tuned such that matching is performed in the matching network.

The calculating of the digital value may include: detecting impedance of the matching network; and receiving the detected impedance signal to determine whether or not the matching network has been matched, and when the matching network has been mismatched, tuning the capacitance to be tuned such that matching is performed in the matching network.

### BRIEF DESCRIPTION OF THE DRAWINGS

FIG. 1 is a circuit diagram schematically illustrating a hybrid variable capacitor according to an embodiment of the present invention;

FIG. 2 is a block diagram schematically illustrating a part in which the hybrid variable capacitor is used in a tunable matching network according to an application example of the present invention;

FIG. 3 is a block diagram schematically illustrating an RF apparatus according to an embodiment of the present invention;

FIG. 4 is a flow chart schematically illustrating a method for tuning a variable capacitor according to another embodiment of the present invention; and

FIG. 5 is a flow chart schematically illustrating a method for tuning a variable capacitor according to another embodiment of the present invention.

### DESCRIPTION OF THE PREFERRED EMBODIMENTS

Exemplary embodiments of the present invention for accomplishing the above-mentioned objects will be described with reference to the accompanying drawings. In describing exemplary embodiments of the present invention, the same reference numerals will be used to describe the same components and an additional description that is overlapped or allow the meaning of the present invention to be restrictively interpreted will be omitted.

In the specification, it will be understood that unless a term such as ‘directly’ is not used in a connection, coupling, or disposition relationship between one component and another component, one component may be ‘directly connected to’, ‘directly coupled to’ or ‘directly disposed to’ another element or be connected to, coupled to, or disposed to another element, having the other element intervening therebetween. In addition, this may also be applied to terms including the meaning of contact such as ‘on’, ‘above’, ‘below’, ‘under’, or the like. In the case in which a standard element is upset or is changed in a direction, terms related to a direction may be interpreted to including a relative direction concept.

Although a singular form is used in the present description, it may include a plural form as long as it is opposite to the concept of the present invention and is not contradictory in view of interpretation or is used as clearly different meaning. It should be understood that “include”, “have”, “comprise”, “be configured to include”, and the like, used in the present description do not exclude presence or addition of one or more other characteristic, component, or a combination thereof.

First, a hybrid variable capacitor according to a first embodiment of the present invention will be described in detail. Here, a reference numeral not described in a referred drawing may be a reference numeral in another drawing denoting the same configuration.

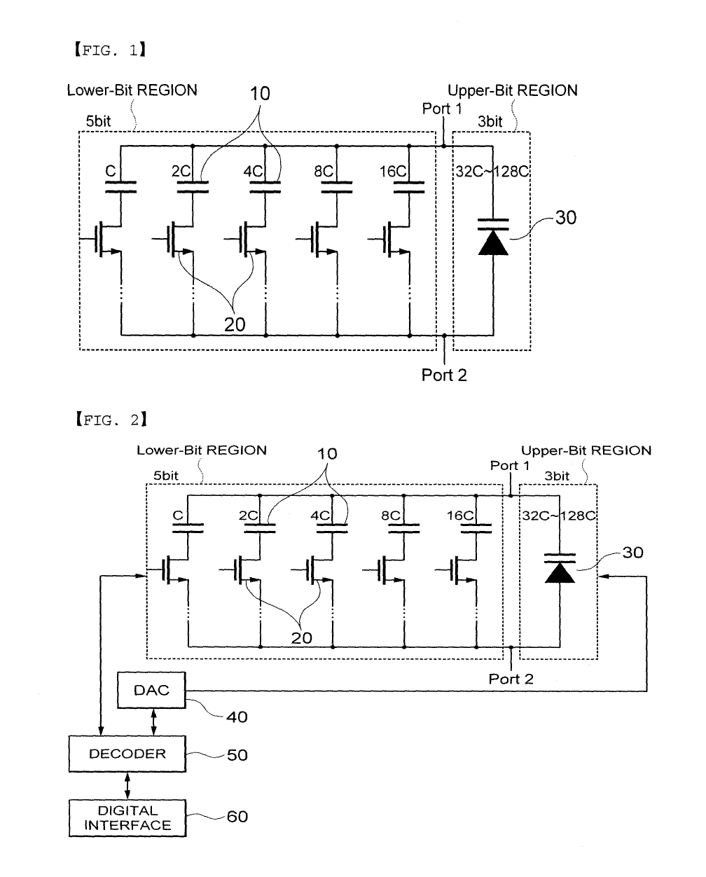

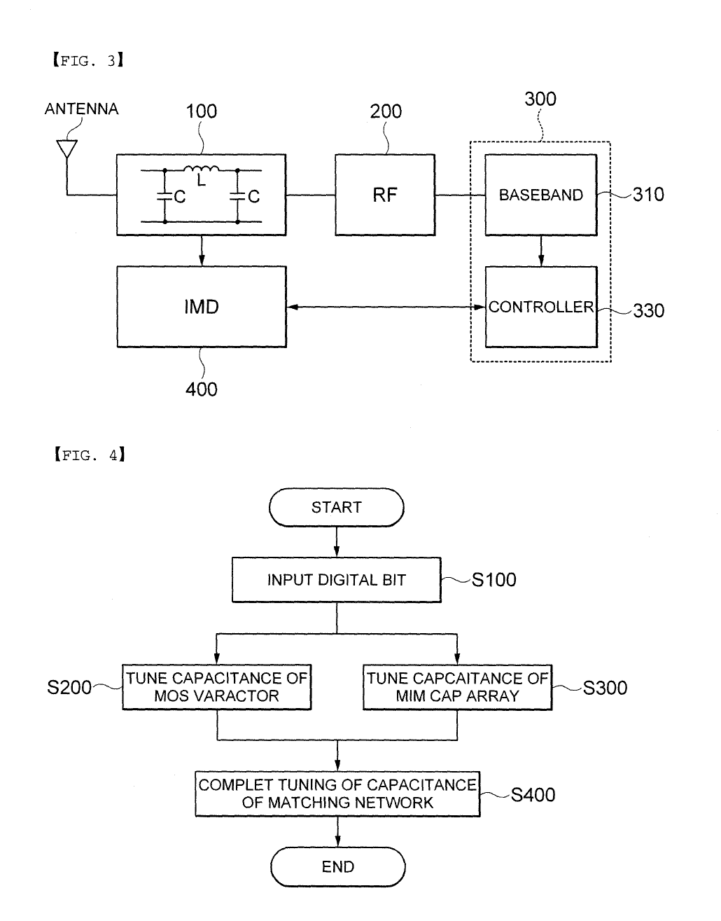

FIG. 1 is a circuit diagram schematically illustrating a hybrid variable capacitor according to an embodiment of the present invention, and FIG. 2 is a block diagram schematically illustrating a part in which the hybrid variable capacitor is used in a tunable matching network according to an application example of the present invention.

Referring to FIGS. 1 and/or 2, the hybrid variable capacitor according to a first embodiment of the present invention is a variable capacitor used for a tunable matching network (100 in FIG. 3). The hybrid variable capacitor may include a metal-insulator-metal (MIM) cap array and a MOS varactor 30.

Here, the MIM cap array includes one or more MIM capacitors 10. The MIM cap array has varied capacitance corresponding to values of a lower-bit region among digital values equivalent to capacitance to be tuned according to controlling.

Here, the MOS varactor 30 may perform coarse tuning, and the MIM cap array may perform fine tuning. The MOS varactor 30 may be supported in a general semiconductor process and vary a capacitance value through a layer in which permittivity is changed according to an applied voltage.

Also, as shown in FIG. 1 and/or FIG. 2, in an example, an FET switch 20 is connected to each of the capacitors of the MIM cap array. One or more FET switches 20 connected to one or more MIM capacitors 10, respectively, perform a switching operation according to values of the lower-bit region among digital values equivalent to capacitance to be tuned. The MIM cap array has varied capacitance according to switching of one or more FET switches 20.

Continuously, with reference to FIG. 1 and/or FIG. 2, the MOS varactor 30 is formed to be connected in parallel to the MIM cap array. Here, the MOS varactor 30 has varied capacitance corresponding to values of an upper-bit region among the digital values equivalent to capacitance to be tuned according to controlling.

Here, the MIM cap array may perform fine tuning and the MOS varactor 30 may perform coarse tuning.

In addition, with reference to FIG. 2, a digital-to-analog converter (DAC) 40 receiving the values of the upper-bit region among the digital values corresponding to the capacitance to be tuned and generating an analog voltage is illustrated. Here, the MOS varactor 30 may have capacitance varied according to the analog voltage generated in the DAC 40 which has received the values of the upper-bit region among the digital values equivalent to the capacitance to be tuned.

Here, the DAC 40 illustrated in FIG. 2 may receive the values of the upper-bit region split from digital values corresponding to capacitance to be tuned from a decoder 50 and generate an analog voltage for controlling variable capacitance of the MOS varactor 30. For example, the decoder 50 may receive digital values corresponding to capacitance to be tuned from a signal processing module 300 illustrated in FIG. 3 and split the digital values into values of an upper-bit region and values of a lower-bit region.

An operation of the hybrid variable capacitor according to the present embodiment will be described together. A hybrid variable capacitor according to an example may be configured to include a MIM cap array including combinations of the MIM capacitors 10 and the FET switches 20 and one or more variable MOS varactors 30 connected in series to the MIM cap array through a semiconductor process, e.g., a CMOS and/or SOI process. Here, one or more MOS varactors 30 may handle the upper-bit region of the variable section and one or more MIM capacitors 10 and the FET switches 20 may handle the lower-bit region of the variable section.

For example, in such a structure, when a control bit is arranged in MSB-LSB order, the MOS varactors 30 are sequentially tuned by the upper-bit region values and the FET switches 20 connected to the MIM capacitors 10 are tuned by the lower-bit region values.

In detail, for example, when values of 11101010 are input through a digital interface 60, MSBs ‘111’ are applied to the varactors 30 and LSBs ‘01010’ are applied to the MIM cap array.

In an embodiment of the present invention, the hybrid variable capacitor employs both the MIM capacitor and the MOS varactor 30 based on the CMOS process. Here, the upper-bit region occupying the largest chip area in the CMOS is tuned by the MOS varactor 30, and the lower-bit region thereof is tuned by the MIM cap array.

For example, the varactor 30 may be fabricated through the CMOS process.

Alternatively, a BST varactor or an external varactor may be associated with the MIM cap array so as to be used.

A second embodiment of the present invention will be described with reference to FIG. 3. Here, the hybrid variable capacitors according to the first embodiment as described above and FIGS. 1 and 2, as well as FIG. 3, may be referred to and repeated descriptions thereof may be omitted.

FIG. 3 is a block diagram schematically illustrating an RF apparatus according to an embodiment of the present invention;

With reference to FIG. 3, an RF apparatus according to the second embodiment of the present invention may include an antenna, a tunable matching network 100, an RF module 200, and a signal processing module 300. In an example, as illustrated in FIG. 3, the RF apparatus may further include an impedance detection unit (IMD) 400. Alternatively, as illustrated in FIG. 3, the RF apparatus may be implemented without the impedance detection unit 400.

In FIG. 3, an antenna transmits an RF signal to the outside or receives an RF signal from the outside. The antenna may be used as a transmission antenna, a reception antenna, or a transmission and reception antenna.

An RF module 200 will be described. The RF module 200 transmits an RF signal to the antenna or receives an RF signal from the antenna. While the antenna performs transmission, the RF module 200 may be an RF transmission module, when the antenna is used as a reception antenna, the RF module 200 may be an RF reception module, and when the antenna is used as a transmission and reception antenna, the RF module 200 may be an RF transceiver module.

Continuously, the matching network 100 in FIG. 3 will be described. Here, the hybrid variable capacitor illustrated in FIG. 1 and/or the capacitor part of the matching network illustrated in FIG. 2 may be referred to.

In FIG. 3, the matching network 100 is installed between the antenna and the RF module 200. For example, as illustrated in FIG. 3, the matching network 100 includes variable capacitor (C) components and an inductor (L) component. Here, impedance matching may be performed by tuning the variable capacitor (C) components. In the matching network 100, capacitance of the variable capacitor (C) components is tuned under the control of the signal processing module 300 to perform matching of a front end of the RF module 200. The variable capacitor (C) components of the matching network 100 in FIG. 3 may be the hybrid variable capacitors according to the first embodiment as described above. Namely, the matching network 100 in FIG. 3 includes the hybrid variable capacitors.

Here, as illustrated in FIG. 1 and/or FIG. 2, the variable capacitor includes the MIM cap array and the MOS varactor 30. The MIM cap array has varied capacitance equivalent to values of the lower-bit region among the digital values corresponding to capacitance to be tuned according to controlling. Also, the MOS varactor 30 is connected in parallel to the MIM cap array and has varied capacitance equivalent to values of the upper-bit region among the digital values corresponding to the capacitance to be tuned according to controlling.

Here, with reference to FIG. 1 and/or FIG. 2, in an example, the hybrid variable capacitor may further include one or more FET switches 20 connected to the respective capacitors of the MIM cap array. Here, the one or more FET switches 20 may perform a switching operation according to the values of the lower-bit region among the digital values corresponding to the capacitance to be tuned to allow the MIM cap array to have varied capacitance under the control of the signal processing module 300.

Also, in an example, the MOS varactor 30 may perform coarse tuning and the MIM cap array may perform fine tuning.

In addition, with reference to FIG. 2, in an example, the matching network 100 may further include the DAC 40 generating an analog voltage for controlling the MOS varactor 30 of the hybrid variable capacitor upon receiving the values of the upper-bit region.

Continuously, with reference to FIG. 2, in an example, the matching network 100 may further include the decoder 50 receiving digital values corresponding to capacitance to be tuned from the signal processing module 300 and splitting the digital values into values of the upper-bit region and values of the lower-bit region. The decoder 50 may be a control logic which receives digital values corresponding to the capacitance to be tuned and splitting the digital values into values of the upper-bit region and the values of the lower-bit region.

Continuously, the signal processing module 300 in FIG. 3 will be described. The signal processing module 300 is connected to a back end of the RF module 200 and processes an RF signal received from the RF module 200 or a signal to be transmitted to the RF module 200. Also, the signal processing module 300 may control capacitance of the hybrid variable capacitor such that matching is performed in the matching network 100.

Another example will be described with reference to FIG. 3.

With reference to FIG. 3, the signal processing module 300 may include a baseband signal processing unit 310 and a controller 330. The baseband signal processing unit 310 processes an RF signal received from the RF module 200 or a signal to be transmitted to the RF module 200.

The controller 330 may control capacitance of the hybrid variable capacitor such that matching is performed in the matching network 100.

Also, in another example, with reference to FIG. 3, the RF apparatus may further include the impedance detection unit 400. The impedance detection unit 400 detects impedance of the matching network 100. A signal detected by the impedance detection unit 400 is transmitted to the signal processing module 300, e.g., to the controller 330, in FIG. 3. Here, the controller 330 may determine whether or not the impedance is mismatched based on the detected signal. When the controller 330 determines that the impedance is mismatched, the controller 330 may tune capacitance such that the matching network 100 is matched.

Next, a method for manufacturing a hybrid variable capacitor according to a third embodiment of the present invention will be described. Here, the hybrid variable capacitors according to the foregoing first embodiment and FIGS. 1 and 2 may be referred to and repeated descriptions thereof may be omitted.

According to the third embodiment of the present invention, the method for manufacturing a hybrid variable capacitor is a method of manufacturing a variable capacitor used in a tunable matching network. Here, the method for manufacturing a hybrid variable capacitor may include forming a MIM cap array and forming the MOS varactor 30.

In the forming of a MIM cap array, a MIM cap array including one or more MIM capacitors 10 is formed on a substrate through a CMOS process so that the capacitance of the MIM cap array is able to be coarsely tuned according to values of a lower-bit region among digital values corresponding to the capacitance of the hybrid variable capacitor to be tuned.

Also, in an example, in the forming of the MIM cap array, the FET switch 20 is formed to be connected to the respective MIM capacitors 10. Here, one or more FET switches 20 connected to the one or more MIM capacitors 10 perform a switching operation according to the values of the lower-bit region among the digital values corresponding to the capacitance to be tuned, to allow the MIM cap array to have varied capacitance.

Next, in the forming of the MOS varactor 30, the MOS varactor 30 is formed to be connected in parallel to the MIM cap array on the substrate through a CMOS process so that the capacitance of the MOS varactor 30 is able to be finely tuned according to values of an upper-bit region among the digital values corresponding to the capacitance of the hybrid variable capacitor to be tuned. The MOS varactor 30 may be supported in a general semiconductor process and a capacitance value is varied through a layer in which permittivity is changed according to an applied voltage.

As the CMOS process according to an embodiment of the present invention, a general bulk process or a CMOS (SOI) process having excellent RF performance may be used.

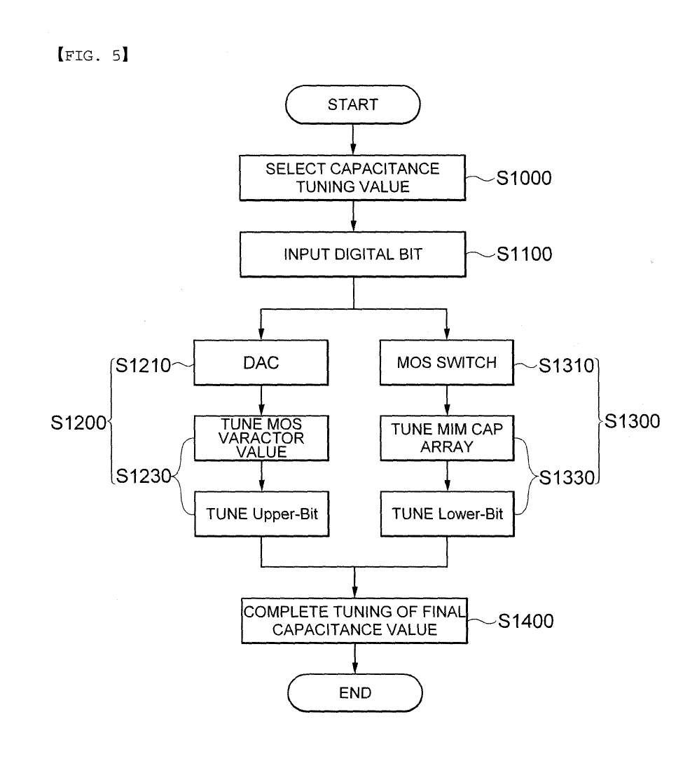

Next, a method for tuning a variable capacitor according to a fourth embodiment of the present invention will be described in detail with reference to the accompanying drawings. Here, the hybrid variable capacitors according to the foregoing first embodiment, the RF apparatuses according to the foregoing second embodiments, and FIGS. 1 through 3, as well as FIGS. 4 and 5, may be referred to and repeated descriptions thereof may be omitted.

FIG. 4 is a flow chart schematically illustrating a method for tuning a variable capacitor according to another embodiment of the present invention, and FIG. 5 is a flow chart schematically illustrating a method for tuning a variable capacitor according to another embodiment of the present invention.

With reference to FIG. 4, the method for tuning a variable capacitor according to the fourth embodiment of the present invention is a variable capacitor tuning method for tuning capacitance of a variable capacitor used in a tunable matching network. Here, the method for tuning a variable capacitor may include a step (S100) of splitting digital values into values of an upper-bit region and values of a lower-bit region, a step (S200) of performing coarse tuning on the MOS varactor 30, a step (S300) of performing fine tuning on an MIM cap array, and a step (S400) of completing tuning of final capacitance.

In FIG. 4, in the step (S100) of splitting digital values into values of an upper-bit region and values of a lower-bit region, digital values corresponding to capacitance to be tuned are received and split into values of an upper-bit region and values of a lower-bit region.

Also, in the step (S100) of splitting digital values into values of an upper-bit region and values of a lower-bit region, digital values corresponding to capacitance to be tuned may be received and split into values of an upper-bit region and values of a lower-bit region according to a control logic.

Next, in the step (S200) of performing coarse tuning on the MOS varactor 30, coarse tuning is performed on the MOS varactor 30 of a hybrid variable capacitor to have varied capacitance equivalent to the values of the upper-bit region split in the previous step. Here, the hybrid variable capacitor comprises a metal-insulator-metal (MIM) cap array and the MOS varactor 30.

In addition, in an example, the step (S200) of performing coarse tuning may include generating of an analog voltage for controlling the MOS varactor 30 upon receiving the values of the upper-bit region.

And then, in the step (S300) of performing fine tuning on the MIM cap array, fine tuning is performed on the MIM cap array to have varied capacitance equivalent to the values of the lower-bit region split in the previous step.

Here, in an example, in the step (S300) of performing fine tuning, the FET switches 20 connected to the respective capacitors of the MIM cap array may perform a switching operation according to the values of the lower-bit region to allow the MIM cap array to have varied capacitance.

Next, in the step (S400) of completing tuning of the final capacitance, the capacitance of the coarsely tuned MOS varactor 30 and the capacitance of the finely tuned MIM cap array are synthesized to complete tuning of the final capacitance.

An embodiment of the method for tuning a variable capacitor will be described with reference to FIG. 5. With reference to FIG. 5, the method for tuning a variable capacitor may further include a step (S1000) of calculating the digital values corresponding to the capacitance to be tuned such that matching is performed in the matching network 100 before a step (S1100) of splitting the digital values into the values of the upper-bit region and the values of the lower-bit region.

Also, in an example, the step (S1000) of calculating the digital values may include a step of detecting impedance of the matching network 100 and a step of tuning capacitance. In the step of detecting impedance of the matching network 100, for example, impedance of the matching network 100 is detected by the impedance detection unit 400 in FIG. 3. Here, the detected signal is transmitted to the signal processing module 300, e.g., the controller 330, in FIG. 3. Thereafter, in the step of tuning capacitance, for example, the controller 330 of FIG. 3 receives the detected impedance signal and determines whether or not the impedance is matched. When the impedance is mismatched, the controller 330 in FIG. 3 tunes the capacitance to be tuned such that matching is performed in the matching network 100.

According to the exemplary embodiments of the present invention, a hybrid variable capacitor required for implementing an effective tunable matching network (TMN) can be provided.

Improvements according to embodiments of the present invention are as follows.

First, in terms of performance, by taking advantages of the varactor and the capacitor array, a tuning range, one of the important characteristics, is extended and a step size is reduced to thereby enhance resolution and perform fine tuning.

Next, in terms of process, the general CMOS process is used for implementation, so it is convenient to integrate digital control blocks.

Also, in terms of price, since the CMOS process is used, the process is stable and a high production yield can be obtained in comparison to the MEMS process or the BST process. Also, since the CMOS process has an edge in price competitiveness, fabrication can be made at low costs.

In addition, according to an embodiment of the present invention, in case of the hybrid variable capacitor, fast switching (1˜2 μs) controlling can be performed, fine tuning can be made in implementing a closed loop.

It is obvious that various effects directly stated according to various exemplary embodiment of the present invention may be derived by those skilled in the art from various configurations according to the exemplary embodiments of the present invention.

The accompanying drawings and the above-mentioned exemplary embodiments have been illustratively provided in order to assist in understanding of those skilled in the art to which the present invention pertains. In addition, the exemplary embodiments according to various combinations of the aforementioned configurations may be obviously implemented by those skilled in the art from the aforementioned detailed explanations. Therefore, various exemplary embodiments of the present invention may be implemented in modified forms without departing from an essential feature of the present invention. In addition, a scope of the present invention should be interpreted according to claims and includes various modifications, alterations, and equivalences made by those skilled in the art.

What is claimed is:

1. A hybrid variable capacitor used in a tunable matching network, the hybrid variable capacitor comprising:
a metal-insulator-metal (MIM) cap array including one or more MIM capacitors and having varied capacitance equivalent to values of a lower-bit region among digital values corresponding to capacitance to be tuned; and
a MOS varactor connected in parallel to the MIM cap array and having varied capacitance equivalent to values of an upper-bit region among the digital values.

2. The hybrid variable capacitor according to claim 1, further comprising:
one or more FET switches connected to the respective capacitors of the MIM cap array and performing a switching operation according to the values of the lower-bit region to allow the MIM cap array to have varied capacitance.

3. The hybrid variable capacitor according to claim 1, wherein the MOS varactor has varied capacitance according to an analog voltage generated from a digital-to-analog converter (DAC) which has received the values of the upper-bit region.

4. The hybrid variable capacitor according to claim 1, wherein the MOS varactor performs coarse tuning, and the MIM cap array performs fine tuning.

5. An RF apparatus comprising:
an antenna;
an RF module transmitting an RF signal to the antenna or receiving an RF signal from the antenna;
a tunable matching network installed between the antenna and the RF module and performing matching on a front end of the RF module by tuning capacitance of a variable capacitor under the control of a signal processing module, the variable capacitor being a hybrid variable capacitor including a metal-insulator-metal (MIM) cap array having varied capacitance equivalent to values of a lower-bit region among digital values corresponding to capacitance to be tuned, and a MOS varactor connected in parallel to the MIM cap array and having varied capacitance equivalent to values of an upper-bit region among the digital values; and
the signal processing module connected to a back end of the RF module, processing an RF signal received from the RF module or a signal to be transmitted to the RF module, and controlling capacitance of the hybrid variable capacitor such that matching is performed in the matching network.

6. The RF apparatus according to claim 5, wherein the hybrid variable capacitor further includes one or more FET switches connected to the respective capacitors of the MIM cap array and performing a switching operation according to the values of the lower-bit region to allow the MIM cap array to have varied capacitance.

7. The RF apparatus according to claim 6, wherein the matching network further includes a digital-to-analog converter (DAC) generating an analog voltage for controlling the MOS varactor of the hybrid variable capacitor upon receiving the values of the upper-bit region.

8. The RF apparatus according to claim 7, wherein the matching network further includes a decoder receiving digital values corresponding to the capacitance to be tuned from the signal processing module and splitting the digital values into the values of the upper-bit region and the values of the lower-bit region.

9. The RF apparatus according to claim 5, wherein the MOS varactor performs coarse tuning, and the MIM cap array performs fine tuning.

10. The RF apparatus according to claims 5, wherein the signal processing module includes:
a baseband signal processing unit processing the RF signal received from the RF module or the signal to be transmitted to the RF module; and
a controller controlling the capacitance of the hybrid variable capacitor such that matching is performed in the matching network.

11. The RF apparatus according to claim 10, further comprising:
an impedance detection unit detecting impedance of the matching network and transmitting the detected signal to the controller to allow the controller to tune the capacitance such that the matching network is matched, when the matching network is mismatched.

12. A method for manufacturing a hybrid variable capacitor used in a tunable matching network, the method comprising:
forming a metal-insulator-metal (MIM) cap array including one or more MIM capacitors on a substrate through a CMOS process so that the capacitance of the MIM cap array is able to be coarsely tuned according to values of a lower-bit region among digital values corresponding to the capacitance of the hybrid variable capacitor to be tuned; and
forming a MOS varactor on the substrate through the CMOS process to be connected in parallel to the MIM cap array so that the capacitance of the MOS varactor is able to be finely tuned according to values of an upper-bit region among the digital values.

13. The method according to claim 12, wherein the forming of the MIM cap array includes forming one or more FET switches which is connected to the respective MIM capacitors and performs a switching operation according to the values of the lower-bit region to allow the MIM cap array to have varied capacitance.

14. A variable capacitor tuning method for tuning capacitance of a variable capacitor used in a tunable matching network, the method comprising:
receiving digital values corresponding to capacitance to be tuned and splitting the digital values into values of a lower-bit region and values of an upper-bit region;
performing coarse tuning on a MOS varactor of a hybrid variable capacitor comprising a metal-insulator-metal (MIM) cap array and the MOS varactor to have varied capacitance equivalent to the split values of the upper-bit region;
performing fine tuning on the MIM cap array to have varied capacitance equivalent to the split values of the lower-bit region; and
completing tuning of the final capacitance by synthesizing the capacitance of the coarsely tuned MOS varactor and the capacitance of the finely tuned MIM cap array.

15. The method according to claim 14, wherein, in the performing of fine tuning, FET switches connected to respective capacitors of the MIM cap array are switched according to the values of the lower-bit region to allow the MIM cap array to have varied capacitance.

16. The method according to claim 15, wherein the performing of coarse tuning includes generating an analog voltage for controlling the MOS varactor upon receiving the values of the upper-bit region.

17. The method according to claim 16, wherein, in the splitting of the digital values into the values of the lower-bit region and the values of the upper-bit region, the digital values corresponding to the capacitance to be tuned are received and split into the values of the lower-bit region and the values of the upper-bit region according to a control logic.

18. The method according to claim 14, further comprising:
calculating the digital values corresponding to the capacitance to be tuned such that matching is performed in the matching network.

19. The method according to claim 18, wherein the calculating of the digital value includes:
detecting impedance of the matching network; and
receiving the detected impedance signal to determine whether or not the matching network has been matched, and when the matching network has been mismatched, tuning the capacitance to be tuned such that matching is performed in the matching network.
